(19) United States
(12) Patent Application Publication
(10) Pub. No.: US 2025/0349521 A1
(43) Pub. Date: Nov. 13, 2025

(54) BATCH PROCESSING CHAMBER WITH WAFER BACKSIDE DEPOSITION PREVENTION

(71) Applicant: Applied Materials, Inc., Santa Clara, CA (US)

(72) Inventors: Vijayabhaskara Venkatagiriyappa, Bangalore (IN); Andrew Nguyen, Gilbert, AZ (US)

(73) Assignee: Applied Materials, Inc., Santa Clara, CA (US)

(21) Appl. No.: 18/662,574

(22) Filed: May 13, 2024

(51) Int. Cl. H01J 37/32; C23C 16/455; C23C 16/458; H01L 21/687

(52) U.S. Cl. CPC H01J 37/32715; C23C 16/45544; C23C 16/4585; H01L 21/68742; H01L 21/68771; H01J 2237/20235; H01J 2237/20278; H01J 2237/332

(57) ABSTRACT

Processing chambers having a chamber body with a wafer cassette assembly and at least one lift pin assembly are described. The wafer cassette assembly has at least two support columns configured to hold a plurality of wafer supports spaced along a height of the support columns. The lift pin assemblies have a plurality of lift pins arranged so that each of the plurality of wafer supports comprises at least three lift pins.

### TECHNICAL FIELD

Embodiments of the disclosure are directed to apparatus and methods for depositing films on a wafer. In particular, embodiments of the disclosure are directed to batch wafer processing atomic layer deposition (ALD) chambers that prevent backside deposition on the wafer.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. To increase production yields, batch processing chambers have been developed that can process multiple wafers at one time.

Some batch processing chambers use a flow of reactive gas across the surfaces of multiple wafers. Current batch processing chambers allow films to be deposited on the front side and back side of the wafer. FIG. 1A illustrates a cross-sectional schematic view of a prior art vertically stacked batch processing chamber 10. FIG. 1B illustrates a top view of the vertically stacked batch processing chamber 10 of FIG. 1A showing the flow of gases in the chamber. In the vertically stacked batch processing chambers 10, wafers 12 are positioned on supports 14 in a spaced apart arrangement. A gas 16 is injected into the processing chamber 10 from a gas inlet 18 to flow across the surface of the wafers 12, as illustrated in FIG. 1B. This type of gas injection not only deposits a film on the top surface 12a of the wafer 12 but also on the back side 12b of the wafer 12. This is not desirable for most films. Even though batch wafer deposition in chambers of this sort improve throughput, the backside deposited film can be an issue for further processing.

Accordingly, there is a need in the art for apparatus and methods for the batch deposition of films on a wafer with minimal to no deposition on the back side of the wafer.

### SUMMARY

One or more embodiments of the disclosure are directed to processing chambers comprising a chamber body, a wafer cassette assembly and at least one lift pin assembly. The chamber body has a top, sidewall and bottom defining an inner chamber region and an outer chamber region. The wafer cassette assembly is inside the chamber body and comprises at least two support columns configured to hold a plurality of wafer supports spaced along a height of the at least two support columns. The at least one lift assembly comprises a plurality of lift pins. The plurality of lift pins are arrange so that each of the plurality of wafer supports comprises at least three lift pins.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a cross-sectional schematic view of a prior art vertically stacked batch processing chamber.

FIG. 1B illustrates a top view of the vertically stacked batch processing chamber of FIG. 1A showing the flow of gases in the chamber.

FIG. 2 illustrates a schematic cross-sectional view of a processing chamber 100 according to one or more embodiments of the disclosure.

FIG. 3 illustrates a schematic cross-sectional view of a portion of a processing chamber illustrating gas flows according to one or more embodiments of the disclosure.

FIG. 4 shows a schematic top view of a processing chamber illustrating loading/unloading of the wafers according to one or more embodiments of the disclosure.

FIG. 5 illustrates a schematic partial cross-sectional view of a wafer being lifted off the plurality of wafer supports by a lift pin according to one or more embodiments of the disclosure.

FIG. 6 illustrates an isometric view of a wafer cassette assembly with wafer supports and a lift pin assembly according to one or more embodiments of the disclosure.

FIG. 7 illustrates a top view of the wafer cassette assembly with wafer supports and lift pin assembly of FIG. 6.

FIG. 8 illustrates an isometric view of the wafer cassette assembly with lift pin assembly of FIG. 6 without the plurality of wafer supports.

FIG. 9 illustrates a top view of the wafer cassette assembly with lift pin assembly of FIG. 8.

FIG. 10 illustrates a partial cross-sectional view of a lift pin assembly and wafer supports according to one or more embodiments of the disclosure.

FIG. 11 illustrates a wafer cassette assembly including at least two support columns, plurality of wafer supports and two lift pin assemblies according to one or more embodiments of the disclosure.

FIG. 12 illustrates the wafer cassette assembly including two support columns and two lift pin assemblies according to one or more embodiments of the disclosure.

FIG. 13 shows a top view of the wafer cassette assembly including two support columns and two lift pin assemblies of FIG. 12.

FIG. 14 shows an expanded view of a portion of the wafer cassette assembly 130 including two support columns and two lift pin assemblies of FIG. 12.

FIG. 15 illustrates a partial cross-sectional view of a wafer on a wafer support with a lift pin according to one or more embodiments of the disclosure.

FIG. 16 illustrates an embodiment of the disclosure in which the contact portion of the pin portion of the lift pin is angled or sloped according to one or more embodiments of the disclosure.

FIG. 17 illustrates a schematic top view of a portion of a processing chamber in which the wafers supports have a smaller outer diameter than the wafer to be positioned on the wafer support according to one or more embodiments of the disclosure.

FIG. 18 shows a cross-sectional view of a portion of the processing chamber of FIG. 17 taken along line 18-18′.

FIG. 19 illustrates a portion of a processing chamber in which there are a plurality of lift pin assemblies and each assembly includes a pulley located outside the chamber bottom to rotate the lift pins according to one or more embodiments of the disclosure.

FIG. 20 illustrates a schematic representation of four lift pin assemblies with pulleys connected by one or more belts according to one or more embodiments of the disclosure.

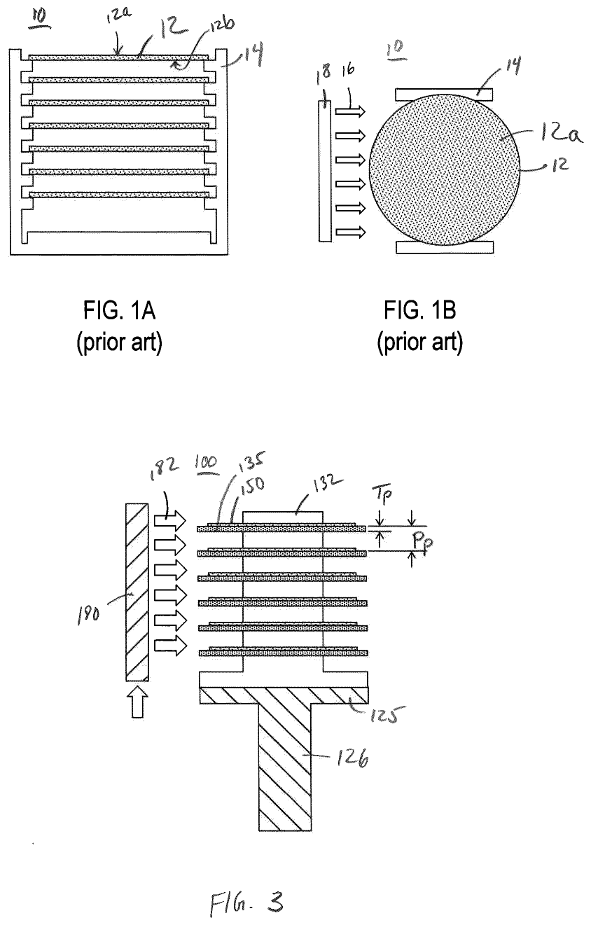

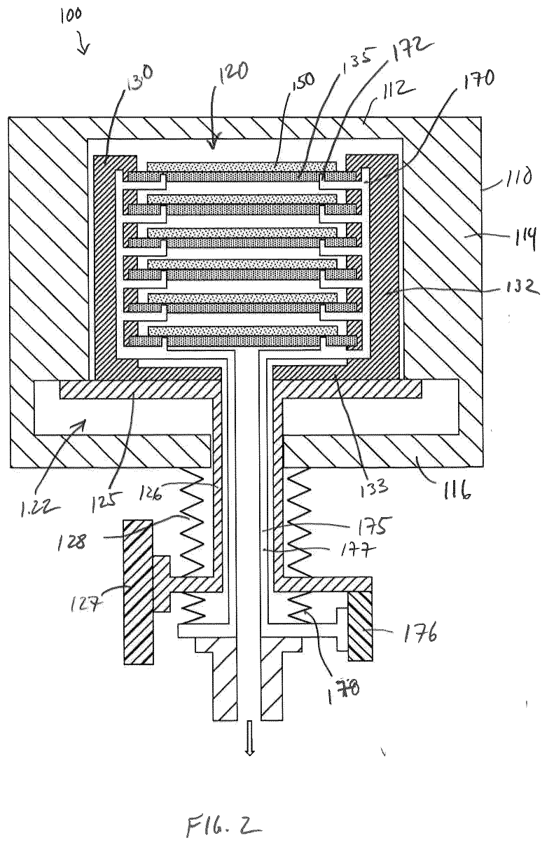

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

PreClean, also known as pre-cleaning, refers to a process in the semiconductor industry that is performed before the actual fabrication of integrated circuits (ICs). Pre-cleaning involves the removal of various contaminants from the surface of the silicon wafer or other substrate materials. PreClean may be an important step in semiconductor manufacturing, depending on the particular process conditions and methods, as pre-cleaning helps to ensure the quality and reliability of the final ICs. The PreClean process typically involves several cleaning steps, including chemical and/or physical methods, to remove particles, organic residues, metal ions, and other impurities from the wafer surface. The specific methods used in PreClean can vary depending on the level of cleanliness intended for subsequent fabrication processes. Some common techniques include, but are not limited to, solvent cleaning, acid cleaning, plasma cleaning, and ultrasonic cleaning.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

The term “about” as used herein means approximately or nearly and in the context of a numerical value or range set forth means a variation of +15% or less, of the numerical value. For example, a value differing by +14%, +10%, +5%, +2%, +1%, +0.5%, or +0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more layers deposited on the substrate or substrate surface by atomic layer deposition (ALD) or plasma-enhanced atomic layer deposition (PEALD) are conformal. As used herein, as will be understood by the skilled artisan, a layer which is “conformal” or “conformally deposited” refers to a layer where the thickness is about the same throughout. A layer/film which is conformal varies in thickness by less than or equal to about 5%, 2%, 1% or 0.5%.

One or more embodiments of the disclosure are directed to batch processing chambers that minimize or eliminate the backside deposition on the wafer. In some embodiments, the wafer cassette is a large thermal mass to allow for faster wafer heating. In some embodiments, the wafers are heated more quickly than for conventional batch processing chambers, reducing process cycle time and power requirements. In some embodiments, unique lift pin designs facilitate wafer lift all at once and hand-off to mutli-blade robot end effectors.

Some embodiments of the disclosure provide unique ways of handling wafers inside the process chamber which prevents process gas flowing along the backside of the wafer. Additionally, as this is a batch wafer chamber, robot hand-off can be a challenge. Some embodiments advantageously provide a different approach in wafer lift design enabling robot access to multiple wafers at a time. The wafer support/substrate will be acting as a thermal mass which helps the wafer to attain steady state temperature faster than existing hardware, reducing the amount of time to pre-heat the wafers before entering the chamber. Some embodiments advantageously increase film quality and throughput. Some embodiments provide a unique lift pin design to facilitate wafer lifting of multiple wafers and hand-off to a multi-blade robot end effector.

In some embodiments, the wafer cassette is designed to handle multiple wafers (e.g., more than 25 wafers). Wafers are transferred to the cassette either singly by a single blade robot, or in batches using a multiple blade robot. The wafers are placed in a vertical pattern (stacking one above the other) on separate (individual) supports. The gas flow through the process chamber is across the surface of the wafers for deposition. In some embodiments, a single pin lift block is designed to lift all of the wafers in the cassette at the same time allowing for easier wafer hand-off. In some embodiments, a separate lift mechanism is designed for the wafer pedestal lift and pin lift and are integrated together.

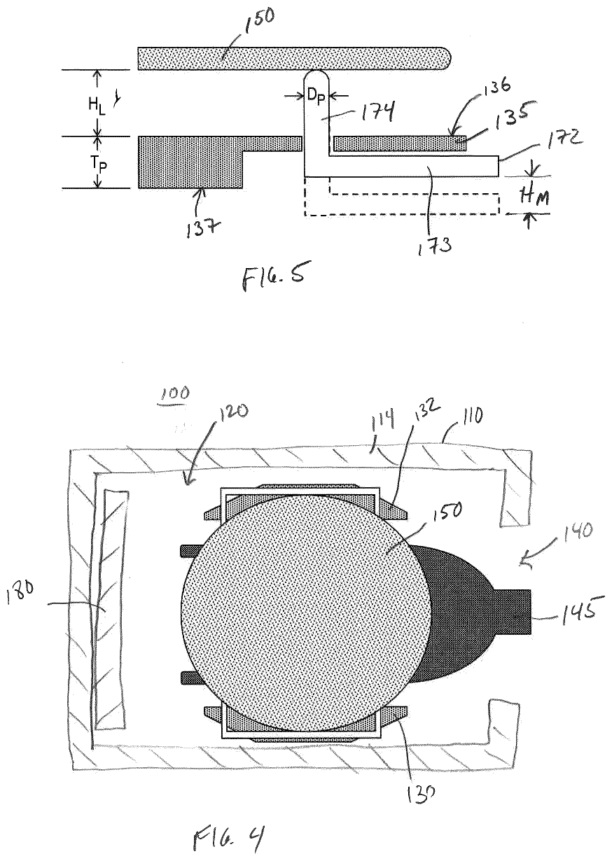

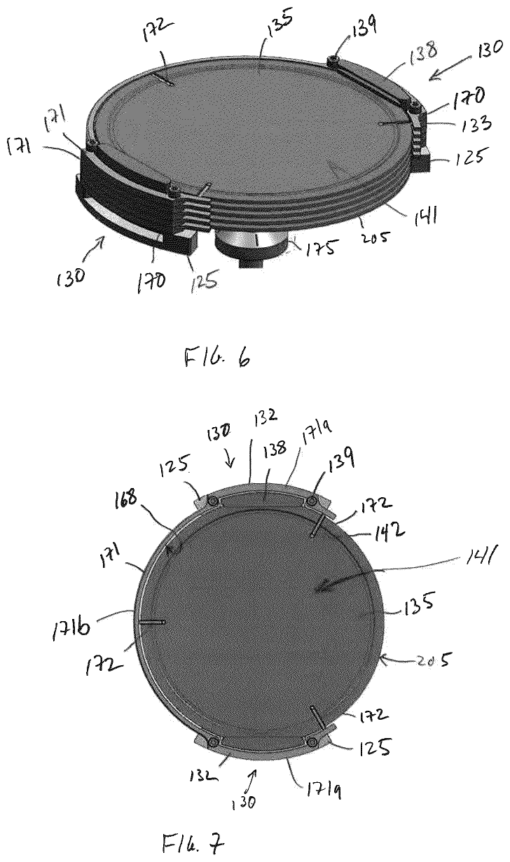

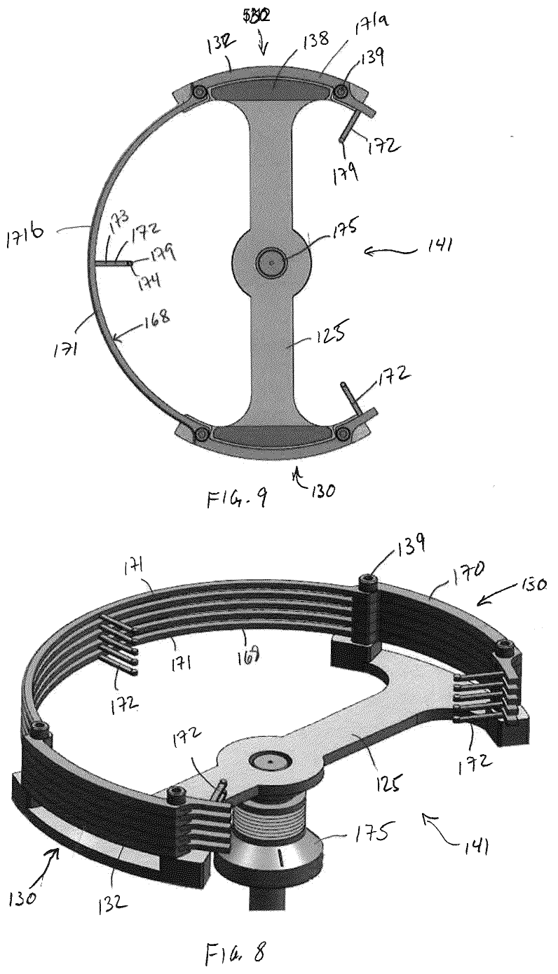

FIG. 2 illustrates a schematic cross-sectional view of a processing chamber 100 according to one or more embodiments of the disclosure. FIG. 3 illustrates a schematic cross-sectional view of a portion of a processing chamber 100 illustrating gas flows. FIG. 4 shows a schematic top view of a processing chamber 100 illustrating loading/unloading of the wafers. The processing chamber 100 has a chamber body 110 with a top 112, sidewall 114 and bottom 116. The chamber body 110 defines an inner chamber region 120 and an outer chamber region 122.

The processing chamber 100 includes a wafer cassette assembly 130 inside the chamber body 110. The wafer cassette assembly 130 comprises at least two support columns 132 configured to hold a plurality of wafers 150, or a plurality of wafer supports 135 spaced along a height of the at least two support columns 132. The wafer cassette assembly 130 of some embodiments further comprises one or more of a floor 133 or ceiling (not shown). The embodiment illustrated in FIGS. 2 and 3 show six wafers 150 on six wafer supports 135. The skilled artisan will recognize that there can be any suitable number of wafers 150 and wafer supports 135. In some embodiments, there are in the range of 5 to 50 wafers supports 135, or in the range of 15 to 25 wafer supports 135.

The wafer cassette assembly 130 and wafer supports 135 can be made of any suitable material known to the skilled artisan. In some embodiments, the wafer cassette assembly 130 (including at least two support columns 132) and/or the plurality of wafer supports 135 comprise aluminum.

The processing chamber 100 further comprises at least one lift pin assembly 170 comprising a plurality of lift pins 172. The plurality of lift pins 172 are arranged so that each of the plurality of wafer supports 135 comprises at least three lift pins 172. The skilled artisan will recognize that three points define a planar surface, and as the wafer 150 is a planar surface, three points of contact (i.e., by three lift pins) are used to prevent destabilization of the wafer 150 during loading/unloading operations.

The lift pins 172 (and optionally the lift pin assembly 170) can be made of any suitable material. In some embodiments, the plurality of lift pins 172 and/or at least one lift pin assembly 170 comprise a dielectric material. For example, suitable materials for the plurality of lift pins 172 and/or the at least one lift pin assembly 170 include, but are not limited to, ceramic.

The sidewall 114 of the chamber body 110 comprises a slit valve 140 to allow a wafer 150 to be loaded or unloaded from the processing chamber 100. In some embodiments, the slit valve 140 is located in the inner chamber region 120 of the chamber body 110 to load and unload wafers 150 from the wafer cassette 160. FIG. 4 illustrates a wafer 150 on a robot 145 extending through the open slit valve 140. The illustration shows the slit valve 140 without a door; however, the skilled artisan will recognize that the slit valve 140 of some embodiments has a door that can be opened and closed to isolate the upper interior region 120 from the conditions outside of the processing chamber body 110.

In the illustrated embodiment, the wafer cassette assembly 130 sits on a pedestal 125 connected to a pedestal lift assembly 126. The pedestal lift assembly 126 includes an actuator 127 (also referred to as a motor) configured to move the pedestal 125 along the height of the stack of wafers 150. Suitable actuators 127 include, but are not limited to, linear guides and servo motors or stepper motors. A bellows 128, or other suitable vacuum isolator, connects the pedestal lift assembly 126 with the chamber body 110 to maintain vacuum within the chamber body 110.

In some embodiments, the pedestal 125 acts as a cathode. For example, in a plasma-enhanced deposition process, the pedestal 125 acts as the cathode with a different component in the processing chamber 100 acting as the anode to generate a plasma within the inner chamber region 120.

The at least one lift pin assembly 170 of some embodiments, further comprises a lift mechanism 175. The lift mechanism 175 can be used to move the at least one lift pin assembly 170 between the inner chamber region 120 and outer chamber region 122 of the chamber body 110. In the illustrated embodiment, the lift mechanism 175 includes an actuator 176 (also referred to as a motor). Suitable actuators 176 include, but are not limited to, linear guides and servo motors or stepper motors. In some embodiments, the actuator 176 is mounted to the pedestal lift assembly 126 and a bellows 178 (or other suitable vacuum isolator) connects the pedestal lift assembly 126 to the lift pin assembly 170 lift mechanism 175.

In the illustrated embodiment, the lift mechanism 175 includes a hollow shaft 177. The hollow shaft 177 of some embodiments is connected to a fore-line or vacuum pump to maintain reduced pressure in the processing chamber 100.

The processing chamber 100 of some embodiments includes a gas injector 180. The gas injector 180 is not visible in the embodiment illustrated in FIG. 2 due to the angle of the view shown. However, a side view and top view showing the gas injector 180 can be found in FIGS. 3 and 4, respectively. The gas injector 180 is configured to provide a flow 182 of gas across the surface of the plurality of wafer supports 135.

In some embodiments, the pedestal 125 further comprises a heater (not shown). In some embodiments, the heater has one heating element. In some embodiments, there is more than one heating element. Multiple heating elements can be arranged in any suitable manner. In some embodiments, the heating elements are arranged in radial zone.

FIG. 5 illustrates a schematic partial cross-sectional view of a wafer 150 being lifted off the plurality of wafer supports 135 by a lift pin 172. Referring to FIGS. 3 and 5, the thickness T_{P} of the plurality of wafer supports 135 measured from the top surface 136 to the bottom surface 137 is in the range of 1 mm to 5 mm or in the range of 1.5 mm to 2.5 mm. The thickness is measured as the thickest portion of the plurality of wafer supports 135 that will be vertically oriented with a wafer 150 during processing. For example, the outer peripheral portions of the plurality of wafer supports 135 outside the diameter of the wafer 150 are not considered in this measurement.

In some embodiments, the pitch P_{P} between the top surfaces 136 of adjacent wafer supports 135 is in the range of 5 mm to 20 mm, or in the range of 7.5 mm to 15 mm, or in the range of 10 mm to 12 mm. In some embodiments, the pitch PP is greater than or equal to 5 mm, 6 mm, 7 mm, 8 mm or 9 mm, and less than or equal to 50 mm, 45 mm, 40 mm, 35 mm, 30 mm, 25 mm, 20 mm, or 15 mm.

Referring to FIG. 5, in some embodiments, the lift pin 172 comprises a pin arm 173 and a pin portion 174. In use, the height H_{M} that the lift pin 172 can move is in the range of 2 mm to 10 mm, or in the range of 3 mm to 8 mm, or in the range of 4 mm to 7 mm, or in the range of 5 mm to 6 mm. The height H_{M} that the lift pin 172 moves depends on, for example, the length of the pin portion of the lift pin 172 and the thickness of the robot 145 end effector. The height H_{L} that the wafer 150 is lifted above the top surface 136 of the plurality of wafer supports 135 during loading/unloading is equal to or less than the height H_{M} that the lift pin 172 can move.

The diameter D_{P} of the pin portion 174 of the lift pin 172 in some embodiments, is in the range of 1 mm to 10 mm, or in the range of 2 mm to 8 mm, or in the range of 3 mm to 6 mm. The contact end of the pin portion 174 can be any suitable shape including, but not limited to, squared, rounded or tapered.

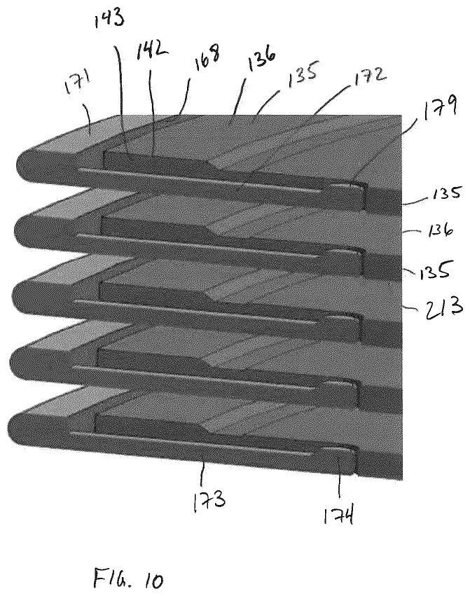

FIG. 6 illustrates an isometric view of a wafer cassette assembly with wafer supports and a lift pin assembly according to one or more embodiments of the disclosure. FIG. 7 illustrates a top view of the wafer cassette assembly with wafer supports and lift pin assembly of FIG. 6. FIG. 8 illustrates an isometric view of the wafer cassette assembly with lift pin assembly of FIG. 6 without the plurality of wafer supports 135. FIG. 9 illustrates a top view of the wafer cassette assembly with lift pin assembly of FIG. 8.

With reference to FIGS. 6 through 9, one or more embodiments of the disclosure are directed to wafer cassette assemblies 130 with wafer supports 135 and at least one lift pin assembly 170. The wafer cassette assembly 130 illustrated includes two support columns 132 connected by the pedestal 125, or floor 133 of the wafer cassette assembly 130. The at least two support columns 132 are the base portion of the wafer cassette assembly 130 upon which the stack of at least one lift pin assembly 170 are positioned with a connector plate 138 and/or connector 139 located at the top of the wafer cassette assembly 130. The embodiment illustrated in FIG. 8 omits the connector plate 138 at the top of the at least two support columns 132 and only includes the connector 139.

In the illustrated embodiment the at least two support columns 132 of the wafer cassette assembly 130 are positioned on opposite sides of the plurality of wafer supports 135. This leaves an unsupported center portion 141 of each plurality of wafer supports 135. The gap between the at least two support columns 132 can be used to allow for unrestricted access by the robot blades for loading/unloading operations.

In some embodiments, as shown in FIGS. 6-9, the lift pin assembly 170 comprises a plurality of lift pin rings 171 extending a portion of a circle around the plurality of wafer supports 135, or around a central region of the wafer cassette assembly 130 leaving an opening or unsupported center portion 141 for a robot blade to access each of the wafer supports.

In some embodiments, where there is one lift pin ring 171 for each plurality of the wafer supports 135, the plurality of lift pin rings 171 extend less than or equal to 300° of a circle, with the remainder open for the robot blade access. In embodiments of the sort, each of the lift pin rings has two support portions 171a located over the at least two support columns, and a connector portion 171b connecting the two support portions 171a (see FIG. 7). In some embodiments, the plurality of lift pin rings 171 extend less than or equal to 270°, 240°, 210° or 195° of a circle, with the remainder open for the robot blade access. In some embodiments, the plurality of lift pin rings 171 extend at least 185° of a circle with the remainder open for the robot blade access.

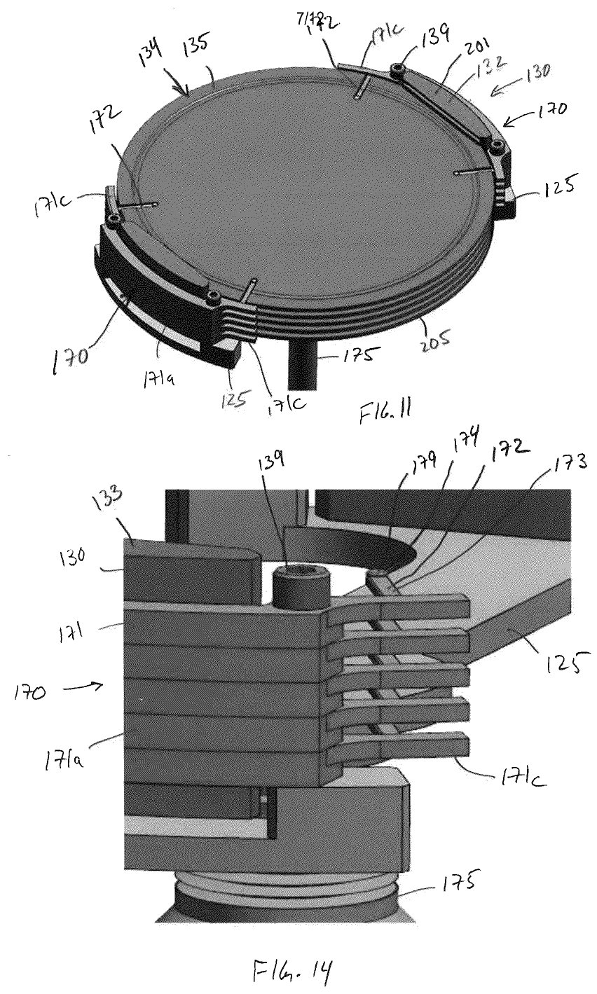

Each of the lift pin rings 171 has at least three lift pins 172. The lift pin 172 extends inwardly from an inner peripheral face 168 of the lift pin ring 171. FIG. 10 illustrates a partial cross-sectional view of a lift pin assembly and wafer supports according to one or more embodiments of the disclosure. With reference to FIG. 10, the lift pin 172 of some embodiments comprises a pin arm 173 with a pin portion 174 at the inner end of the pin arm 173. The pin portion 174 includes a contact surface 179 at the inner end of the lift pin 172 furthest from the inner peripheral face 168 of the lift pin ring 171.

In operation, the lift mechanism 175 is moved by actuator 176 to elevate the lift pins 172 through slit openings 142 in the plurality of wafer supports 135. The slit openings 142 are sized to minimize space between the sides of the lift pins 172 and the inside face 143 of the slit openings 142 without allowing contact between the lift pin 172 and the inside face 143 of the slit openings 142 to prevent particulate formation. In some embodiments, there is at least 0.25 mm between the sides of the lift pin 172 and the inside face 143 of the slit openings 142.

During processing, the contact surface 179 of the pin portion 174 of the lift pin 172 is positioned coplanar with or below the top surface 136 of the plurality of wafer supports 135. In some embodiments, the contact surface 179 of the pin portion 174 of the lift pin 172 is positioned in the range of 0.1 mm to 1 mm below the top surface 136 of the plurality of wafer supports 135, or in the range of 0.2 mm to 0.9 mm, or in the range of 0.3 mm to 0.8 mm or in the range of 0.4 mm to 0.6 mm below the top surface 136 of the plurality of wafer supports 135.

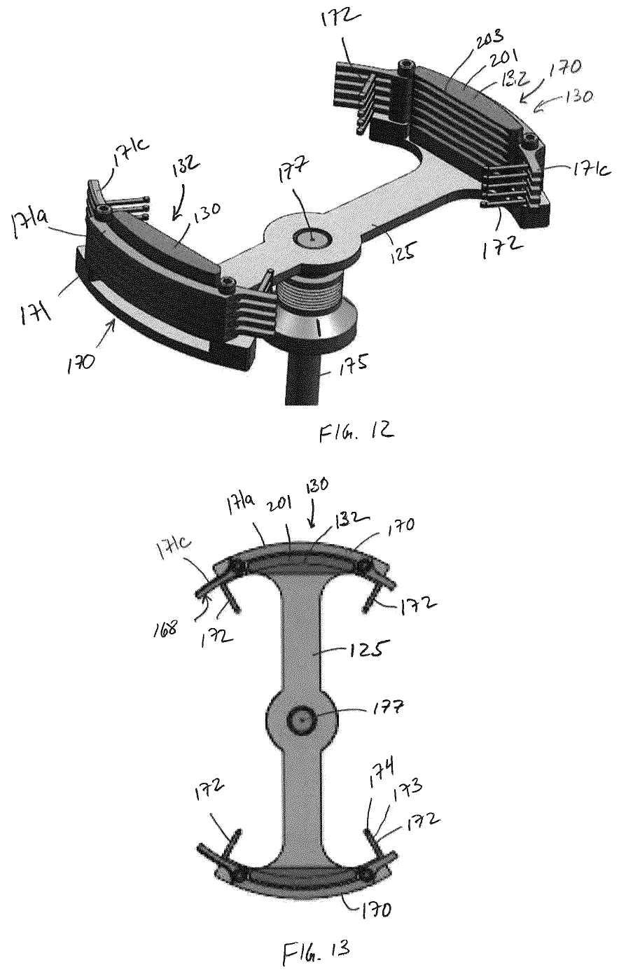

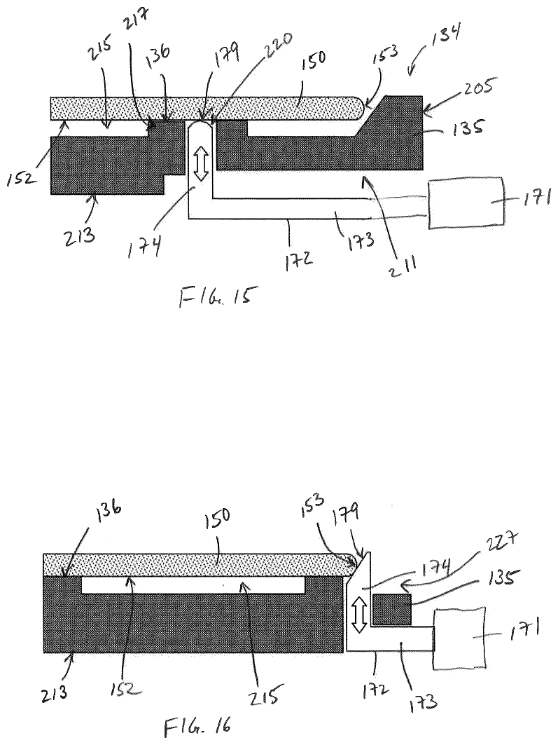

FIG. 11 illustrates a wafer cassette assembly 130 including at least two support columns 132, plurality of wafer supports 135 and two lift pin assemblies 170. FIG. 12 illustrates the wafer cassette assembly 130 including two support columns 132 and two lift pin assemblies 170. FIG. 13 shows a top view of the wafer cassette assembly 130 including two support columns 132 and two lift pin assemblies 170 of FIG. 12. FIG. 14 shows an expanded view of a portion of the wafer cassette assembly 130 including two support columns 132 and two lift pin assemblies 170 of FIG. 12.

Referring to FIGS. 11 through 14, some embodiments of the disclosure comprise at least two wafer cassette assemblies 130 including at least two support columns 132. The support columns 132 of the wafer cassette assembly 130 illustrated have a support column body 201 positioned on opposite sides of the pedestal 125, relative to the hollow shaft 177 of the lift mechanism 175. The support column body 201 of some embodiments comprises a plurality of vertically spaced channels 203. As shown in FIG. 11, the vertically spaced channels 203 are configured to support the outer peripheral edges 134 of the plurality of wafer supports 135.

The at least one lift pin assembly 170 is positioned on the pedestal 125 and includes a support portion 171a adjacent to the support column body 201 of the support columns 132 and an extension wing 171c extending from the support portion 171 in a arcuate path around the outer peripheral face 205 of the outer peripheral edges 134 of the plurality of wafer supports 135. In some embodiments, the plurality of lift pin rings 171 are positioned on opposite sides of the wafer supports 135, relative to the center of the wafer supports 135 of the hollow shaft 177 of the lift mechanism 175.

In the embodiment illustrated in FIGS. 11 through 14, each of the lift pin rings 171 have two lift pins 172. In some embodiments, one of the lift pin rings 171 has two lift pins 172 and the other of the lift pin rings 171 has one lift pin 172 so that there are three lift pins for each of the plurality of wafer supports 135.

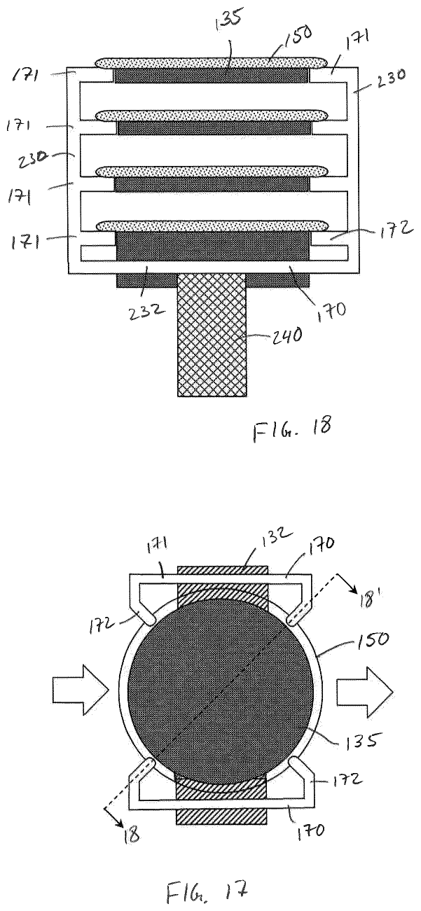

FIG. 15 illustrates a partial cross-sectional view of a wafer 150 on a wafer support 135 with a lift pin 172. The lift pins 172 comprise a pin arm 173 extending inwardly from the lift pin ring 171 for a distance and a pin portion 174 angled upwardly from the pin arm 173. In the illustrated embodiments, the wafer support 135 comprises a recess 211 in the bottom surface 213 of the wafer support 135. The recess 211 is located around an outer peripheral edge 134 of the wafer support 135.

An opening 220 through the wafer support 135 is configured to allow the pin portion 174 of the lift pins 172 to extend through the opening 220 when the lift pin 172 are in the loading/unloading position. The embodiment illustrated in FIG. 15 has the lift pin 172 in the process position so that the wafer 150 is on the top surface 136 of the wafer support 135. In the illustrated embodiment, when the lift pin 172 is raised to the loading/unloading position, the pin arm 173 portion of the lift pin 172 moves into the recess 211 in the bottom surface 213 of the wafer support 135.

The openings 220 of some embodiments are inset from the outer peripheral edge 134, or the outer peripheral face 205, of the wafer support 135 so that the contact surface 179 of the pin portion 174 of the lift pin 172 contacts the wafer 150 in the field of the bottom surface 152 of the wafer 150. Stated differently, the openings 220 of some embodiments are offset from the outer peripheral face 205 or outer peripheral edges 134 of the wafer support 135 so that the contact surface 179 of the pin portion 174 of the lift pin 172 contacts the bottom surface 152 of the wafer 150 rather than the outer peripheral edge 153 of the wafer 150.

In some embodiments, the top surface 136 of the wafer support 135 includes a recessed inner portion 215 with raised portions 217 around each of the openings 220. The recessed inner portion 215 of some embodiments helps minimize contact with the bottom surface 152 of the wafer 150 to prevent damage or particulate formation. The raised portions 217 of the top surface 136 of the wafer support 135 of some embodiments are offset from the outer peripheral face 205 of the wafer support 135, or offset from the outer peripheral edge 153 of the wafer 150.

FIG. 16 illustrates an embodiment of the disclosure in which the contact portion 179 of the pin portion 174 of the lift pin 172 is angled or sloped. In use the sloped surface of the pin portion 174 contacts the outer peripheral edge 153 of the wafer 150. In the illustrated embodiment, the wafer support 135 includes a recessed inner portion 215 in the top surface 136 of the wafer support 135. The outer peripheral edge 134 of the wafer support 135 in the illustrated embodiment includes a recessed top portion 227. The recessed top portion 227 of the outer peripheral edges 134 of the wafer support 135 is positioned so that the outer peripheral edge 153 of the wafer 150 extends over the recessed top portion 227.

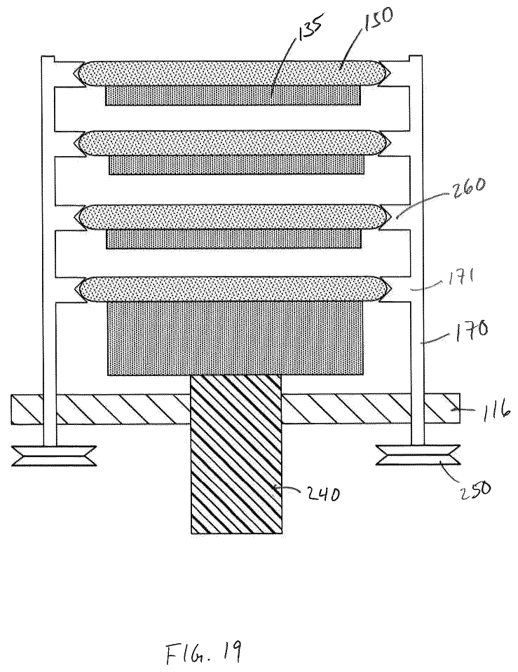

FIG. 17 illustrates a schematic top view of a portion of a processing chamber in which the wafers supports 135 have a smaller outer diameter than the wafer 150 to be positioned on the wafer support 135. In the illustrated embodiment, the wafer 150 is illustrated as transparent for descriptive purposes. FIG. 18 shows a cross-sectional view of a portion of the processing chamber of FIG. 17 taken along line 18-18′.

The embodiment illustrated in FIGS. 17 and 18 allow for the wafers 150 to be supported by the wafer supports 135 and moved with the lift pins 172 without having openings through which the lift pins 172 move. In some embodiments, the wafer support 135 is circular with a substantially uniform offset from the wafer 150 so that the amount of wafer 150 extending past the outer peripheral edge of the wafer support 135 is about the same around the wafer periphery. In some embodiments, the wafer support 135 is irregularly shaped with the outer peripheral edge of the wafer support 135 extending inwardly at the regions where the lift pins 172 are located. In embodiments of the this sort, the outer edge of the wafer 150 can be in contact with the top surface of the wafer support 135 around the majority of the surface, with only the lift pin portions being unsupported by the wafer support during processing. In some embodiments, the wafer support 135 has an outer diameter that is in the range of 1 mm to 10 mm smaller than the wafer 150, or in the range of 2 mm to 8 mm smaller than the wafer 150, or in the range of 3 mm to 6 mm smaller than the wafer 150.

The at least one lift pin assembly 170 of some embodiments, is positioned outside an outer peripheral edge of the wafer supports 135. The at least one lift pin assembly 170 comprises a plurality of lift pin rings 171 connected vertically with a lift pin assembly arm 230 and a lift pin assembly bottom 232. The term “ring” used in lift pin rings 171 has an expanded meaning and is not limited to circular, semicircular or arcuate shapes. The term “ring” refers to a portion of a lift pin assembly that connects more than one lift pin 172. For example, FIG. 17 shows a top view of the lift pin assembly 170 with the plurality of lift pin rings 171 connecting two adjacent lift pins 172, and in FIG. 18, the lift pin assembly arm 230 vertically connects four lift pin rings 171 and the lift pin assembly bottom 232. The lift pin assembly 170 of the illustrated embodiment is positioned on a shaft 240. The shaft 240 of some embodiments comprises a steel body with one or more channels for a cooling fluid. The shaft 240 can be moved vertically by the actuator 176 and in some embodiments is connected to a cooling fluid source configured to flow a cooling fluid through the shaft 240 to cool the lift pin assembly bottom 232 and the lift pin assembly 170.

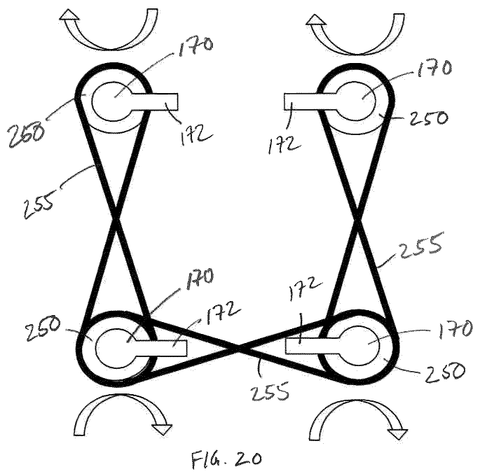

FIG. 19 illustrates a portion of a processing chamber in which there are a plurality of lift pin assemblies 170 and each assembly includes a pulley 250 located outside the chamber bottom 116 to rotate the lift pins 172. In the embodiment of FIG. 19, the lift pins are replaced with v-shaped fingers 260. The at least one lift pin assembly 170 can be rotated by the connected pulley 250 so that the v-shaped fingers 260 rotate within the plane of the wafer 150 so that the outer peripheral edge of the wafer is captured by the v-shape so that vertical movement of the at least one lift pin assembly 170 results in vertical movement of the wafer 150. The embodiment shown in FIG. 19 has the v-shaped fingers 260, and the at least one lift pin assembly 170 rotated in a loading/unloading position in which the outer peripheral edge of the wafer 150 is engaged with the v-shaped finger 260. The skilled artisan will recognize that rotation of the pulley 250 can rotate the at least one lift pin assembly 170 so that the v-shaped fingers 260 are in a process position in which the edges of the wafers 150 are not engaged with the v-shaped fingers 260.

In some embodiments, the process for loading the wafer 150 comprises moving the wafer 150 into the process chamber using the robot end effector, rotating the v-shaped fingers 260 on the at least one lift pin assembly 170 so that the v-shape engages the outer peripheral edge of the wafer, and then retracting the robot end effector. The at least one lift pin assembly 170 can then be lowered to position the wafers 150 on the wafer support 135. The v-shaped fingers 260 can remain engaged with the wafers 150 during processing, or can be rotated that the v-shape is not in contact with the wafer edge.

FIG. 20 illustrates a schematic representation of four lift pin assemblies 170 with pulleys 250 connected by one or more belts 255. Rotation of one of the pulleys 250 in the illustrated connected arrangement will result in rotation of all four of the lift pin assemblies 170 at the same time. This allows a single rotation motor to be connected to one pulley 250 and to cause simultaneous rotation of all lift pin assemblies 170.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A processing chamber comprising:
a chamber body having a top, sidewall and bottom defining an inner chamber region and an outer chamber region;
a wafer cassette assembly inside the chamber body, the wafer cassette comprising at least two support columns configured to hold a plurality of wafer supports spaced along a height of the at least two support columns; and
at least one lift pin assembly comprising a plurality of lift pins, the plurality of lift pins arranged so that each of the plurality of wafer supports comprises at least three lift pins.

2. The processing chamber of claim 1, further comprising a motor configured to move the wafer cassette assembly from the inner chamber region to the outer chamber region.

3. The processing chamber of claim 1, wherein there are two support columns positioned on opposite sides of the wafer supports leaving an unsupported center portion of each wafer support.

4. The processing chamber of claim 3, wherein the lift pin assembly comprises a plurality of lift pin rings extending a portion of a circle leaving an opening for a robot blade to access each of the wafer supports.

5. The processing chamber of claim 4, wherein the plurality of lift pin rings extend less than or equal to 240°.

6. The processing chamber of claim 4, wherein each of the lift pin rings has three lift pins extending inwardly.

7. The processing chamber of claim 3, wherein there are two lift pin rings positioned on opposite sides of the wafer supports.

8. The processing chamber of claim 7, wherein each of the lift pin rings have two lift pins.

9. The processing chamber of claim 3, wherein each of the lift pins comprise a pin arm extending inwardly from the lift pin ring for a distance and a pin angled upwardly from the pin arm.

10. The processing chamber of claim 9, wherein each of the wafer supports comprises a recess in a bottom of the wafer support around an outer peripheral edge of the wafer support, and an opening for each of the lift pins to allow a contact portion of each pin to extend through the opening when the lift pins are in a loading position.

11. The processing chamber of claim 10, wherein when the lift pin are in the loading position, the pins arm move into the recesses.

12. The processing chamber of claim 11, wherein the openings are inset from the outer peripheral edge of the wafer support and are positioned to allow the contact portion of the lift pins to contact a bottom surface of the wafer when in the loading position.

13. The processing chamber of claim 12, wherein a top surface of the wafer support has a recessed inner portion with raised portions around each of the openings.

14. The processing chamber of claim 11, wherein the openings are inset from the outer peripheral edge of the wafer support so that the contact portion of the lift pins engage the outer peripheral edge of the wafer when in the loading position.

15. The processing chamber of claim 14, wherein the contact portion of the lift pin is angled.

16. The processing chamber of claim 3, wherein each of the lift pins comprise a pin arm extending inwardly from the lift pin ring with a pin end that project upwardly from the pin arm.

17. The processing chamber of claim 16, wherein there are a plurality of slit openings in the wafer supports configured to allow the pin arm and pin end to move through the slit openings.

18. The processing chamber of claim 3, wherein the wafer supports have a smaller outer diameter than a wafer to be positioned on the wafer support and the lift pin is positioned outside an outer peripheral edge of the wafer supports.

19. The processing chamber of claim 3, wherein there are plurality of lift pin assemblies and each of the lift pin assemblies further comprise a pulley located outside the chamber bottom to rotate the lift pins from a loading position to a process position.

20. The processing chamber of claim 19, further comprising one or more belt connecting the pulleys to cause simultaneous rotation of all lift pin assemblies.
